(19) United States
(12) Patent Application Publication
(10) Pub. No.: US 2010/0318310 A1
(43) Pub. Date: Dec. 16, 2010

(54) Off-Chip Supply Of Calibration Data

(75) Inventor: Volker Thomas, Gilching (DE)

Correspondence Address: SpryIP, LLC IFX, 5009 163rd PL SE, Bellevue, WA, 98006, US

(73) Assignee: Infineon Technologies AG, Neubiberg (DE)

(21) Appl. No.: 12/484,678

(22) Filed: Jun. 15, 2009

(51) Int. Cl. G01R 35/00

(52) U.S. Cl. 702/107

(57) ABSTRACT

The present disclosure relates to off-chip supply of calibration data.

### BACKGROUND

Wireless chips and other integrated circuits often include functions with analog characteristics subject to variation due to process spread, changes in ambient conditions (e.g. temperature), and changes in electrical conditions (e.g. supply voltage). For example, filters, in-phase/quadrature phase mismatch compensation circuits, bias circuits, and others may not be able to operate properly over the range of values produced by some processes. In some instances, the peripheral circuits around the integrated circuits may be designed to tolerate large parameter spreads. However, by designing the peripheral circuits to tolerate specified parameter spreads, performance of the peripheral circuits can increase unnecessarily and result in higher current consumption of the integrated circuit. Additionally, the cost to produce the required peripheral circuits may be relatively high. In other instances, parameter spreads can be reduced by on-chip calibration circuits. For example, integrated circuit manufacturers may limit the range of certain critical parameters by writing compensation values into electrical fuses or flash memory of the integrated circuit. However, on-chip calibration circuits may be inaccurate, increase die area of the integrated circuit, increase power consumption, produce timing issues, and/or provide unwanted interference.

### BRIEF DESCRIPTION OF THE DRAWINGS

The detailed description is described with reference to the accompanying figures. In the figures, the left-most digit(s) of a reference number identifies the figure in which the reference number first appears. The use of the same reference numbers in different instances in the description and the figures may indicate similar or identical items.

FIG. 1 is a diagrammatic view of a system supplying off-chip calibration data.

FIG. 2 is a diagrammatic view of a system to supply off-chip calibration data to a computing device via a network.

FIG. 3 is a flow diagram of a method to store calibration data of an integrated circuit on a computer-readable storage medium separate from the integrated circuit.

FIG. 4 is a flow diagram of a method to write calibration data accessed from a computer-readable storage medium to memory of a computing device, where the computer-readable storage medium is separate from the computing device and separate from the integrated circuit.

FIG. 5 is a flow diagram of a method to supply calibration data of an integrated circuit of a computing device to the computing device via a network.

### DETAILED DESCRIPTION

Disclosed herein are techniques to provide calibration data of an integrated circuit without storing the calibration data on the integrated circuit. Storing the calibration data off-chip may be cost-saving because less die area is utilized. Additionally, by storing calibration data off-chip less writing time is needed during chip production testing because the calibration data does not need to be written onto the integrated circuit.

According to one implementation, a computing device comprises a network interface, processing logic, and memory accessible to the processing logic. The memory includes a calibration data module configured to receive calibration data of an integrated circuit of the computing device from a server coupled to a remote database via the network interface. The calibration data module is also configured to store the calibration data in the memory of the computing device and calibrate the integrated circuit based on the calibration data.

According to another implementation, a method comprises incorporating an integrated circuit into a computing device and retrieving an identifier of the integrated circuit. The method also comprises accessing calibration data of the integrated circuit from a computer-readable storage medium based on the identifier, where the computer-readable storage medium is separate from the computing device and separate from the integrated circuit. In addition, the method comprises writing the calibration data to memory of the computing device.

According to still another implementation, one or more computer-readable storage media comprise computer executable instructions that, when executed by a computer, perform acts comprising generating calibration data for an integrated circuit and writing a unique identifier to the integrated circuit. Additionally, the one or more computer-readable storage media comprise computer executable instructions that, when executed by the computer, perform further acts comprising storing calibration data on an additional computer-readable storage medium in association with the unique identifier, where the additional computer-readable storage medium is separate from the integrated circuit.

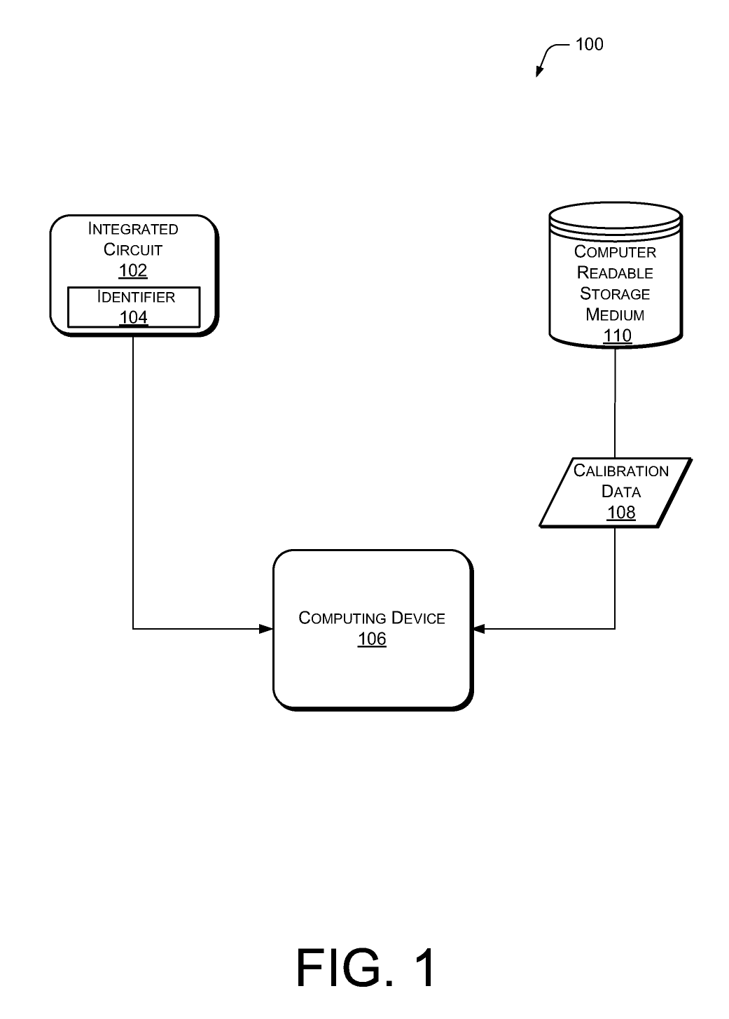

FIG. 1 is a diagrammatic view of a system 100 to supply off-chip calibration data. The system 100 includes an integrated circuit 102 having an identifier 104. The identifier 104 may be a unique identifier assigned by a manufacturer of the integrated circuit 102. The identifier 104 may be written to components of the integrated circuit 102, such as electronic fuses, or to memory (e.g. flash memory) of the integrated circuit 102. Additionally, the identifier 104 may be encoded as a bar code, written as an alphanumeric string, or stored within a radio frequency identification tag. The identifier 104 may be located on the integrated circuit 102 and/or on packaging associated with the integrated circuit 102.

The integrated circuit 102 includes a number of semiconductor devices to perform functions during operation of a computing device, such as the computing device 106. The computing device 106 may be a personal computer, a laptop computer, a personal digital assistant (PDA), a portable gaming device, a wireless communication device, such as a smart phone or mobile handset, a set-top-box, a game console, a portable music player, another consumer electronic device, any other device including an integrated circuit, or any combination thereof. An integrated circuit manufacturer may send the integrated circuit 102 to a computing device manufacturer that incorporates the integrated circuit 102 into the computing device 106. For example, an integrated circuit manufacturer may provide a radio frequency transceiver integrated circuit to a smart phone or mobile handset manufacturer that incorporates the particular integrated circuit into the smart phone or mobile handset.

In some instances, the integrated circuit 102 may be associated with calibration data 108 that includes numeric data, such as compensation values to regulate certain parameters of the integrated circuit 102. In other instances, the calibration data 108 may include software instructions executable by a processor of the computing device 106 to maintain operating conditions of the computing device 106 such that process spread is within specified limits. The manufacturer of the integrated circuit 102 may obtain the calibration data 108 during testing of a wafer including the integrated circuit or in chip back-end testing. In some instances, the calibration data 108 may be unique for each integrated circuit sample tested.

After obtaining the calibration data 108, the manufacturer of the integrated circuit 102 may write the calibration data 108 to a computer-readable storage medium 110. In an illustrative embodiment, the computer-readable storage medium 110 may be a stand-alone portable memory device, such as a compact disc or a flash memory stick. Thus, the manufacturer of the integrated circuit 102 can provide the computer-readable storage medium 110 to the manufacturer of the computing device 106 upon purchase of the integrated circuit 102. The manufacturer of the computing device 106 can then download the calibration data 108 from the computer-readable storage medium 110 and write the calibration data 108 to memory of the computing device 106.

In another illustrative embodiment, the computer-readable storage medium 110 may include one or more fixed storage devices, such as a hard disk drive, volatile memory, such as random access memory (RAM), nonvolatile memory, such as read-only memory (ROM), removable memory, and/or non-removable memory, EEPROM, flash memory, optical storage devices, magnetic cassettes, magnetic tape, magnetic disk storage or other magnetic storage devices, or any other medium which can be used to store the calibration data 108. In this illustrative embodiment, the computer-readable storage medium 110 may be included in a database maintained by the manufacturer of the integrated circuit 102, by the manufacturer of the computing device 106, by a third-party entity, or a combination thereof. A database including the computer-readable storage medium 110 may be accessible via a network. In one example, the calibration data 108 may be retrieved from the computer-readable storage medium 110 via the network by the manufacturer of the computing device 106 and subsequently written to memory of the computing device 106 to facilitate proper operation of the computing device 106. In another example, the manufacturer of the integrated circuit 102 may access the calibration data 108 for quality control purposes, such as fault analysis reporting, for generating additional calibration data for the integrated circuit 102 or for other integrated circuits, to determine testing parameters of other integrated circuits, or a combination thereof.

In yet another illustrative embodiment, the computing device 106 may directly access a database including the computer-readable storage medium 110 to retrieve the calibration data 108 via a network. For example, the manufacturer of the computing device 106 may initially write the calibration data 108 to RAM of the computing device 106 and the calibration data 108 may be removed from the RAM when the computing device 106 is turned off or upon loss of power to the memory of the computing device 106. In this example, a start-up procedure of the computing device 106 may include downloading the calibration data 108 from a remote database including the computer-readable storage medium 110. In another example, the manufacturer of the computing device 106 may write the calibration data 108 to ROM of the computing device 106. In this example, the computing device 106 may receive additional calibration data or a different version of the calibration data 108 from a remote database as an update. The computing device 106 may subsequently write the newly received calibration data to the ROM of the computing device 106 in addition to the calibration data 108 already stored in the ROM or overwrite the calibration data 108 with the updated calibration data. Thus, in either example, where the calibration data 108 is written to RAM or ROM of the computing device 106, an older version of calibration data may be replaced by an updated version. The updated version may be provided by the manufacturer of the integrated circuit 102, the manufacturer of the computing device 106, or a combination thereof.

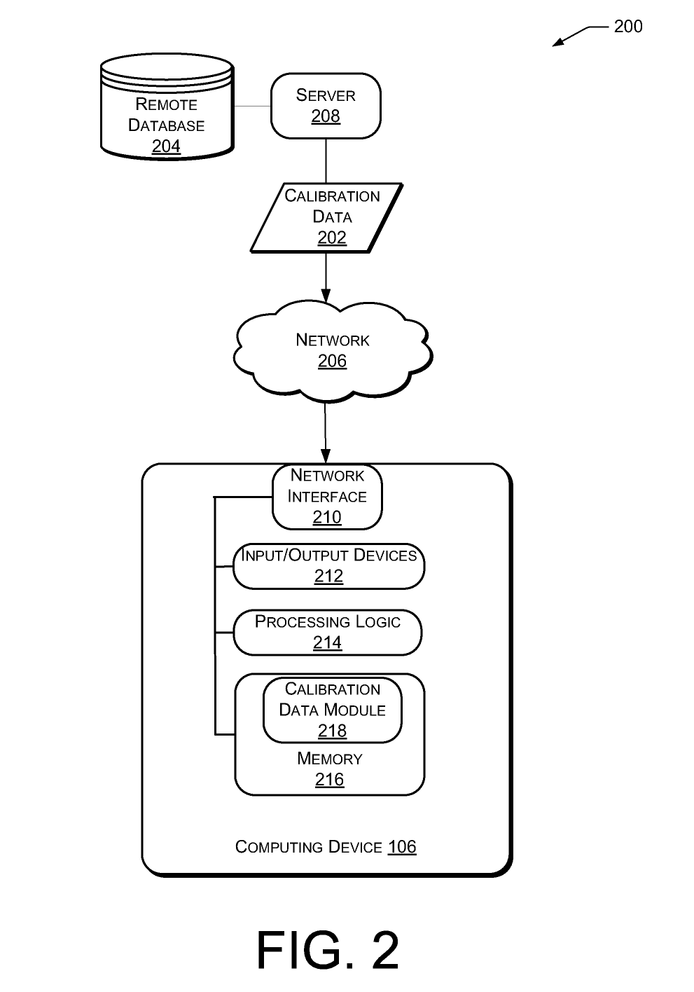

FIG. 2 is a diagrammatic view of a system 200 to supply off-chip calibration data 202 to a computing device 106 from a remote database 204 via a network 206. The remote database 204 may store the calibration data 202 on a computer-readable storage medium, such as the computer-readable storage medium 110 of FIG. 1. In addition, the remote database 204 is coupled to a server 208 to provide the calibration data 202 to the computing device 106. The calibration data 202 includes calibration data for one or more integrated circuits of the computing device 106. For example, the calibration data 202 may include original calibration data provided by the respective manufacturers of the one or more integrated circuits of the computing device 106 or updated calibration data. In some embodiments, the remote database 204 may include calibration data associated with a number of integrated circuits made by one or more integrated circuit manufacturers. Additionally, or alternatively, the remote database 204 may include calibration data associated with integrated circuits that have been placed in computing devices made by the one or more computing device manufacturers, such as a manufacturer of the computing device 106. Further, the remote database 204 may be maintained by one or more computing device manufacturers, by one or more integrated circuit manufacturers, by a third-party entity, such as a service provider for the computing device 106 (e.g. a wireless communications service provider), or a combination thereof. The network 206 may include a local area network, a wide area wired network, such as a public switched telephone network (PSTN) or a cable television network, a satellite network, a collection of networks, a wide area wireless network, a wireless local area network, a public Internet Protocol (IP) network, a private IP network, or a combination thereof.

The computing device 106 includes a network interface 210 and one or more input/output devices 212. The network interface 210 is configured to facilitate communications between the remote database 202 and the computing device 106 via the network 206. Additionally, the input/output devices 212 may include a keypad, a cursor control device, such as a mouse pad or thumb stick, a display, a touch screen display device, a microphone, a speaker, or a combination thereof. The computing device 106 also includes processing logic 214, such as one or more processors, and memory 216. The memory 216 may be accessible to the processing logic 214 and may include volatile and non-volatile storage media, such as random access memory (RAM) and read-only memory (ROM), flash memory, one or more hard disk drives, optical storage devices, or a combination thereof. The memory 216 may also include instructions embodied in one or more computer-readable software programs and/or hardware logic to facilitate operation of the computing device 106, such as a Web browsing application and/or an operating system among others.

In a particular embodiment, the memory 216 includes a calibration data module 218 implemented as software and/or hardware executable by the processing logic 214. The calibration data module 218 is configured to receive calibration data of an integrated circuit of the computing device from the remote database 204 via the network interface 210 and store the calibration data 202 in the memory 214. The calibration data may be stored in random access memory of the computing device 106, read-only memory of the computing device 106, flash memory of the computing device 106, in other storage devices of the computing device 106, or a combination thereof. The calibration data module 218 is also configured to calibrate one or more integrated circuits of the computing device 106 based on the calibration data 202.

In an illustrative embodiment, the calibration data module 218 is configured to send a request to the remote database 204 for the calibration data 202. For example, the computing device 106 may store calibration data in RAM and send a request for the calibration data 202 during a start-up procedure or in response to a loss of power at the memory 216. The request may include identifiers of one or more integrated circuits of the computing device 106, such as the identifier 104 of the integrated circuit 102 in FIG. 1. In response to receiving the request from the computing device 106, the server 208 coupled to the remote database 204 may retrieve calibration data associated with the one or more integrated circuits of the request based on the identifiers of the one or more integrated circuits and send the corresponding calibration data 202 to the computing device 106. In some embodiments, the calibration data module 218 may be configured to send multiple requests to multiple remote databases, where the calibration data associated with integrated circuits of the computing device 106 is stored in different remote databases. Additionally, the calibration data module 218 may send requests for calibration data associated with some integrated circuits of the computing device 106, but not others. To illustrate, during the start-up procedure, the calibration data module 218 may be configured to send a calibration data request the remote database 204 to retrieve calibration data for integrated circuits with calibration data stored in RAM, but not for integrated circuits with calibration data stored in ROM or not for integrated circuits that are not associated with remotely stored calibration data.

In another example, the calibration data module 218 is configured to send a calibration data request to the remote database 204 in response to improper operation of the computing device 106. To illustrate, the memory 216 may include error correction software to detect errors in the operation of the computing device 106. If the error correction software determines that the error may relate to improper operation of particular integrated circuits, the calibration data module 218 may be invoked to send a calibration data request to the remote database 204 to retrieve calibration data associated with the particular integrated circuits. In still another example, the calibration data module 218 may be configured to send a calibration data request to the remote database 204 in response to input by a user of the computing device 106. To illustrate, a user of the computing device 106 may utilize the input/output devices 212 to send a calibration data request to the remote database 204 when the user observes an error in operation of the computing device 106 or when the computing device 106 alerts the user that certain errors have occurred with respect to operation of the computing device 106.

In another illustrative embodiment, the server 208 may initiate communication with the computing device 106 to send the calibration data 202 to the computing device 106. For example, the server 208 may determine that updated calibration data associated with one or more integrated circuits of the computing device 106 has been stored at the remote database 204. Consequently, the server 208 may retrieve the corresponding calibration data from the remote database 204 and send the calibration data 202 to the computing device 106. In an illustrative, non-limiting embodiment, the calibration data 202 may be included in a larger set of information associated with the computing device 106, such as a software patch or other configuration data that is sent from the remote database 204.

After the computing device 106 receives the calibration data 202 from the remote database 204, the calibration data module 218 may be configured to store the calibration data 202 in the memory 216, such as RAM or ROM. In some instances, the calibration data module 218 is configured to overwrite existing calibration data stored in the memory 216 with the calibration data 202. In other instances, the calibration data 202 serves as an update to calibration data already stored in the memory 216. The calibration data module 218 may then be configured to calibrate the one or more integrated circuits of the computing device 106 associated with the calibration data 202.

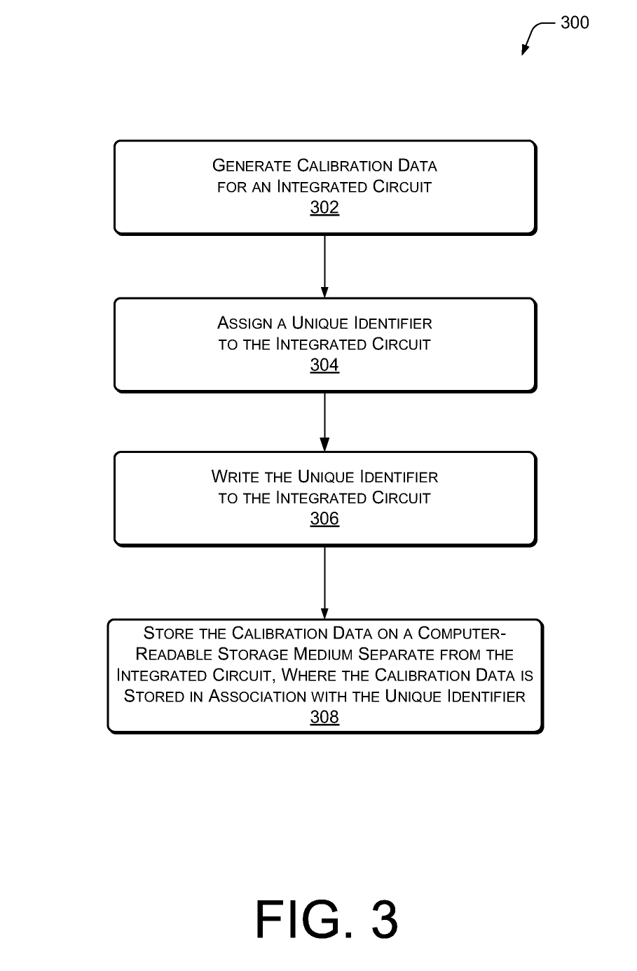

FIGS. 3-5 include flow diagrams of illustrative methods of supplying off-chip calibration data. The methods of FIGS. 3-5 may be implemented, in whole or in part, using one or more computer-readable storage media including instructions executable by a processor.

FIG. 3 is flow diagram of a method 300 to store calibration data of an integrated circuit on a computer-readable storage medium separate from the integrated circuit. The method 300 begins at 302 with generating calibration data for an integrated circuit, such as the integrated circuit 102 of FIG. 1. The calibration data is configured to control process spread to facilitate proper operation of the integrated circuit. The calibration data may be generated by a manufacturer of the integrated circuit. For example, the calibration data may be generated during testing of a wafer including the integrated circuit or during chip back-end testing. At 304, a unique identifier is assigned to the integrated circuit, for example, by the manufacturer of the integrated circuit. At 306, the unique identifier is written to the integrated circuit. In one example, the unique identifier may be written to an electronic fuse of the integrated circuit. In another example, the unique identifier may be represented by a bar code, alphanumeric string, or stored in a radio-frequency identification (RFID) tag. The bar code, alphanumeric string, or RFID tag may be located on the integrated circuit or located on packaging associated with the integrated circuit. At 308, calibration data is stored on a computer-readable storage medium in association with the unique identifier. That is, the calibration data may be retrieved from the computer-readable storage medium based on the unique identifier assigned to the integrated circuit. In addition, the computer-readable storage medium is separate from the integrated circuit. For example, the computer-readable storage medium may include a portable memory device, such as a compact disc or a flash memory stick, or the computer-readable storage medium may include a fixed memory device, such as a hard disk drive. Further, the computer-readable storage medium may be included in a network accessible remote storage system maintained by the manufacturer of the integrated circuit. In some embodiments, the calibration data is stored in association with a respective digital signature.

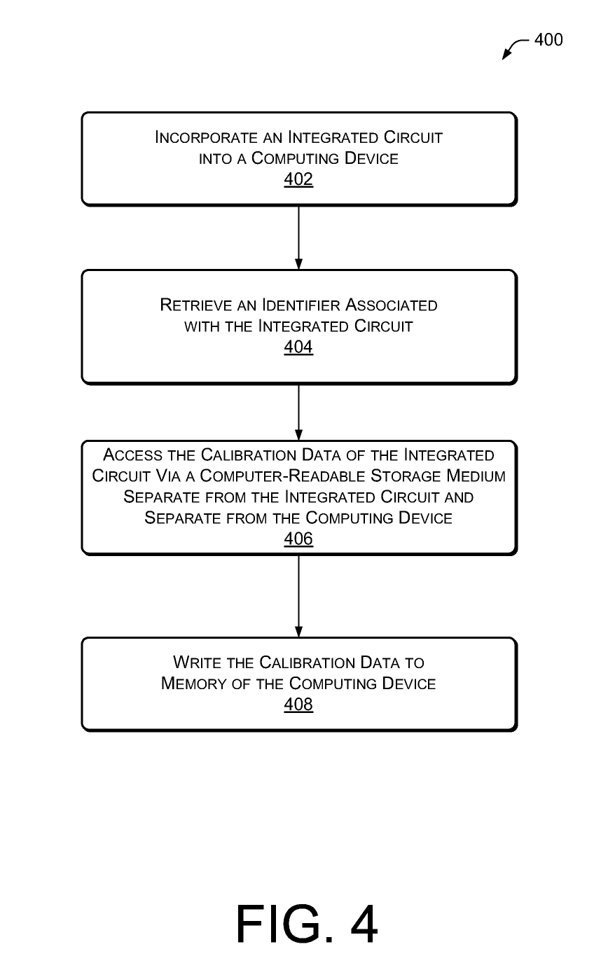

FIG. 4 is a flow diagram of a method 400 to write calibration data accessed from a computer-readable storage medium to memory of a computing device, where the computer-readable storage medium is separate from the computing device and separate from the integrated circuit. The method 400 begins at 402 by incorporating an integrated circuit into a computing device. The integrated circuit may be the integrated circuit 102 of FIG. 1 and the computing device may be the computing device 106 of FIG. 1 and FIG. 2. The integrated circuit may be incorporated into the computing device by a manufacturer of the computing device, where the integrated circuit is configured to perform functions related to the operation of the computing device. At 404, an identifier of the integrated circuit is retrieved. In some embodiments, the identifier of the integrated circuit may be retrieved by reading the identifier from an electronic fuse of the integrated circuit. In other embodiments, the identifier of the integrated circuit may be retrieved from a memory device of the integrated circuit, such as a flash memory device. Further, the identifier of the integrated circuit may be retrieved by reading a bar code or alphanumeric code associated with the integrated circuit or by retrieving data from a radio-frequency identification tag associated with the integrated circuit.

At 406, calibration data of the integrated circuit is accessed from a computer-readable storage medium based on the identifier. The computer-readable storage medium is separate from the computing device and separate from the integrated circuit. To illustrate, the calibration data may be accessed from a compact disc, flash memory stick, or other portable storage medium provided to a manufacturer of the computing device by the manufacturer of the integrated circuit. The calibration data may also be accessed from a computer-readable storage medium that is included in a database coupled to a remote server. For example, a manufacturer of the computing device may access the calibration data stored on a remote database via a website provided by the manufacturer of the integrated circuit. After retrieving the calibration data from the remote database, a manufacturer of the computing device may store the calibration data at a computer or database located in a facility operated by the manufacturer of the computing device.

At 408, the calibration data is written to memory of the computing device. For example, the calibration data may be written to RAM or ROM of the computing device. In this way, the calibration data may be accessed by the computing device to calibrate the integrated circuit and facilitate proper operation of the integrated circuit. The calibration data may also be customized by the manufacturer of the computing device before writing the calibration data to the memory of the computing device. For example, the calibration data may be modified based on process spreads or other operating conditions, such as providing a particular supply voltage, that may occur during operation of the computing device.

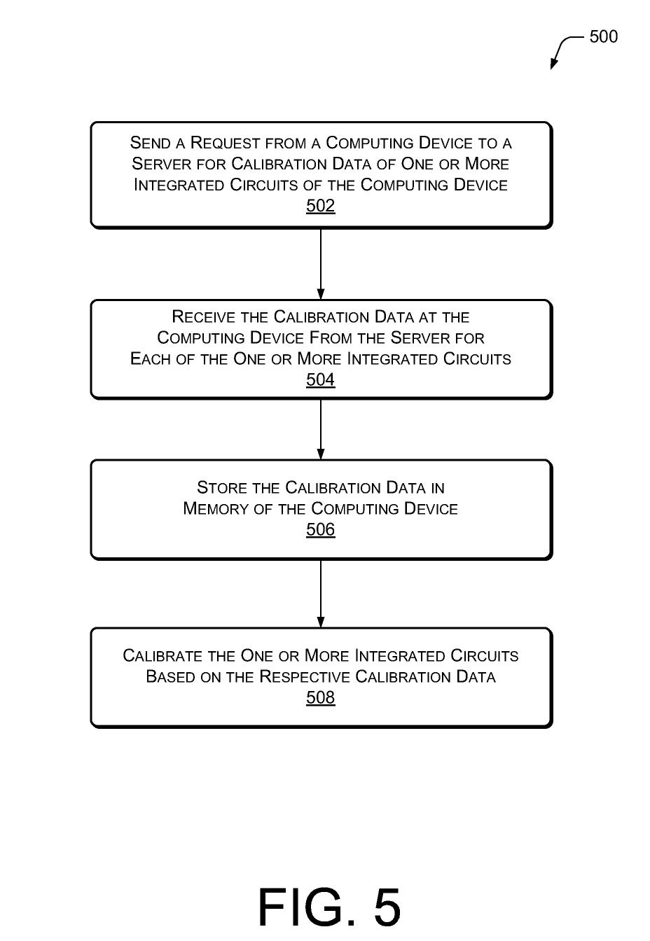

FIG. 5 is a flow diagram of a method 500 to supply calibration data of an integrated circuit of a computing device to the computing device via a network. The method 500 begins at 502 by sending a request from a computing device to a server for calibration data of one or more integrated circuits of the computing device. In some embodiments, the request may be sent during start-up of the computing device. In other embodiments, the request may be sent after receiving a notification from the server indicating that an update to calibration data stored at the computing device is available. The server may be accessible to the computing device via a network, such as a public Internet Protocol network or a wide area wireless data network, and coupled to a remote database including the requested calibration data. Further, the server may be maintained by a manufacturer of the one or more integrated circuits of the computing device or maintained by the manufacturer of the computing device. At 504, the calibration data is received at the computing device from the server for each of the one or more integrated circuits. At 506, the calibration data is stored in memory of the computing device. The calibration data may be stored in RAM, ROM, or some other storage device of the computing device. At 508, the one or more integrated circuits of the computing device are calibrated based on the respective calibration data.

Conclusion

For the purposes of this disclosure and the claims that follow, the terms “coupled” and “connected” have been used to describe how various elements interface. Such described interfacing of various elements may be either direct or indirect. Although the subject matter has been described in language specific to structural features and/or methodological acts, it is to be understood that the subject matter defined in the appended claims is not necessarily limited to the specific features or acts described. Rather, the specific features and acts are disclosed as preferred forms of implementing the claims. The specific features and acts described herein and variations of these specific features and acts may be implemented separately or may be combined.

1. A computing device comprising:
a network interface;
processing logic; and
memory accessible to the processing logic, the memory comprising a calibration data module configured to:
receive calibration data of an integrated circuit of the computing device from a server coupled to a remote database via the network interface;
store the calibration data in the memory; and
calibrate the integrated circuit based on the calibration data.

2. The computing device of claim 1, wherein the calibration data module is configured to send a request to the server for the calibration data.

3. The computing device of claim 2, wherein the memory further comprises error correction software to:
detect errors in operation of the computing device; and
invoke the calibration data module to send the request for the calibration data of the integrated circuit to the server when an error in operation of the computing device relates to the integrated circuit.

4. The computing device of claim 2, wherein the calibration data module is configured to send the request for the calibration data of the integrated circuit during a start-up procedure of the computing device.

5. The computing device of claim 2, wherein the request for the calibration data of the integrated circuit is sent to the server in response to user input received via input/output devices of the computing device.

6. The computing device of claim 1, wherein the calibration data module is configured to receive updated calibration data from the server.

7. The computing device of claim 1, wherein the calibration data is included in a software patch for the computing device.

8. The computing device of claim 1, wherein the calibration data module is configured to receive calibration data from the server for an additional integrated circuit of the computing device.

9. A method comprising:
incorporating an integrated circuit into a computing device;
retrieving an identifier of the integrated circuit;
accessing calibration data of the integrated circuit from a computer-readable storage medium based on the identifier, wherein the computer-readable storage medium is separate from the computing device and separate from the integrated circuit; and
writing the calibration data to memory of the computing device.

10. The method of claim 9, wherein the identifier of the integrated circuit is retrieved by reading the identifier from an electronic fuse of the integrated circuit.

11. The method of claim 9, wherein the identifier of the integrated circuit is retrieved by reading a bar code associated with the integrated circuit.

12. The method of claim 9, wherein the identifier is retrieved from a radio-frequency identification (RFID) tag associated with the integrated circuit.

13. The method of claim 9, wherein the computer-readable storage medium is included in a database coupled to a remote server.

14. The method of claim 13, wherein the database is maintained by one or more computing device manufacturers, by one or more integrated circuit manufacturers, by a third-party entity, or a combination thereof.

15. The method of claim 9, wherein the calibration data is customized before writing the calibration data to the memory of the computing device.

16. The method of claim 9, wherein the calibration data is supplied by a manufacturer of the integrated circuit.

17. One or more computer-readable storage media comprising computer executable instructions that, when executed by a computer, perform acts comprising:
generating calibration data for an integrated circuit;
writing a unique identifier to the integrated circuit; and
storing calibration data on an additional computer-readable storage medium in association with the unique identifier, wherein the additional computer-readable storage medium is separate from the integrated circuit.

18. The one or more computer-readable storage media of claim 17, wherein the unique identifier is written to an electronic fuse of the integrated circuit.

19. The one or more computer-readable storage media of claim 17, wherein the calibration data is stored in association with a respective digital signature.

20. The one or more computer-readable storage media of claim 17, wherein the calibration data is generated during testing of a wafer including the integrated circuit.
